(19) United States
(12) Patent Application Publication
(10) Pub. No.: US 2025/0112444 A1
(43) Pub. Date: Apr. 3, 2025

(54) METHOD FOR FORMING WET OXIDATION APERTURE SHAPE OF VCSEL DEVICE

(71) Applicant: Taiwan-Asia Semiconductor Corporation, Hsinchu City (TW)

(72) Inventor: Shang-Che LEE, Hsinchu City (TW)

(21) Appl. No.: 18/783,128

(22) Filed: Jul. 24, 2024

(30) Foreign Application Priority Data
Oct. 2, 2023 (TW) 112137689

(51) Int. Cl. H01S 5/183

(52) U.S. Cl. CPC H01S 5/18311

(57) ABSTRACT

A method for forming a wet oxidation aperture shape of a VCSEL device, including: placing a VCSEL wafer having a circular VCSEL mesa with a diameter of 25 um-30 um into a wet oxidation furnace; vacuumizing the wet oxidation furnace; ramping up a temperature of the wet oxidation furnace to 250-350° C. and maintaining for a first period, and introducing N₂ and H₂O gases into the wet oxidation furnace during the first period; continuously introducing N₂ and H₂O gases, while ramping up the temperature to 350-450° C. and maintaining for a second period; continuously introducing N₂ and H₂O gases, while ramping up the temperature to 400-450° C. and maintaining for a third period; maintaining 400-450° C. to initiate oxidation of the VCSEL wafer; after the oxidation is completed, introducing N₂ gas into the wet oxidation furnace to cool it down to 150° C.; and taking out the VCSEL wafer.

### CROSS-REFERENCES TO RELATED APPLICATIONS

This application claims priority to Taiwan Patent Application No. 112137689 filed on Oct. 2, 2023, which is hereby incorporated by reference in its entirety.

### BACKGROUND OF THE INVENTION

### Field of the Invention

The present invention relates to a vertical cavity surface emitting laser (VCSEL) device, particularly a method for forming a wet oxidation aperture shape of a VCSEL device.

### Descriptions of the Related Art

In recent years, VCSEL devices have been widely used as light sources in consumer electronics (e.g., virtual reality (VR) sensing devices).

It is well known that the wet oxidation aperture shapes of the epitaxial layers of the 650 nm VCSEL devices are diamond-shaped or shield-shaped, and the wet oxygen aperture shapes are rarely circular. In the conventional technology, only the wet oxidation aperture shapes of the epitaxial layers of the 940 nm VCSEL devices are approximately circular. However, since the 650 nm VCSEL device and the 940 nm VCSEL device have inherent differences in the structure and growth characteristics of the epitaxial layers, it has not been possible to effectively control the wet oxidation aperture shape of the epitaxial layer of the 650 nm VCSEL device to be similar to the wet oxidation aperture shape of the epitaxial layer of the 940 nm VCSEL device which is approximately circular.

Given this, how to form the wet oxidation aperture shape of the epitaxial layer of the 650 nm VCSEL device into a circular shape is an urgent issue for the industry to solve.

### SUMMARY OF THE INVENTION

The objective of the present invention is to improve the stability of the 650 nm VCSEL device and increase its reliability and tolerance by adjusting and improving the operation parameters of the wet oxidation furnace so as to form the wet oxidation aperture shape of the epitaxial layer of the 650 nm VCSEL device to be substantially circular.

To achieve the above objective, the present invention discloses a method for forming a wet oxidation aperture shape of a VCSEL device. The method includes the following steps: placing a VCSEL wafer into a wet oxidation furnace, the VCSEL wafer having a circular VCSEL mesa with a diameter of 25 um-30 um; vacuumizing the wet oxidation furnace; ramping up a temperature of the wet oxidation furnace to 250-350° C. and maintaining for a first period, and introducing N₂ gas and H₂O gas into the wet oxidation furnace during the first period; continuously introducing the N₂ gas and the H₂O gas into the wet oxidation furnace, while ramping up the temperature of the wet oxidation furnace to 350-450° C. and maintaining for a second period; continuously introducing the N₂ gas and the H₂O gas into the wet oxidation furnace, while ramping up the temperature of the wet oxidation furnace to 400-450° C. and maintaining for a third period; maintaining the wet oxidation furnace at 400-450° C. to initiate oxidation of the VCSEL wafer; after the oxidation of the VCSEL wafer is completed, introducing the N₂ gas into the wet oxidation furnace to cool the wet oxidation furnace down to 150° C.; and after cooling to 150° C., taking the VCSEL wafer out of the wet oxidation furnace.

In an example, before placing the VCSEL wafer into the wet oxidation furnace, the method further includes the following steps: when a wet oxidation process machine is in a standby state, introducing the N₂ gas and the H₂O gas into the wet oxidation furnace to confirm whether a flow rate of the N₂ gas and a flow rate of the H₂O gas are normal; and after confirming that the flow rate of the N₂ gas and the flow rate of the H₂O gas are normal, placing the VCSEL wafer into the wet oxidation furnace.

In an example, the N₂ gas is introduced into the wet oxidation furnace at 10 liters/minute (L/min).

In an example, the H₂O gas is introduced into the wet oxidation furnace at 2 grams/hour (g/h).

In an example, the temperature of the wet oxidation furnace is ramped up to 250-350° C. at a rate of 10˜40° C./min.

In an example, the first period is 6-8 minutes.

In an example, the temperature of the wet oxidation furnace ramped up to 350-450° C. is ramped up at a rate of 10˜30° C./min.

In an example, the second period is 1-2 minutes.

In an example, the temperature of the wet oxidation furnace ramped up to 400-450° C. is ramped up at a rate of 10˜25° C./min.

In an example, the third period is 1-2 minutes.

In an example, the method further includes the following step: taking the VCSEL wafer out of the wet oxidation furnace and allowing the VCSEL wafer to cool naturally at room temperature.

After referring to the drawings and the detailed description of embodiments described later, those of ordinary skill in the art can understand other objectives of the present invention, as well as the technical means and implementations of the present invention.

### BRIEF DESCRIPTION OF THE DRAWINGS

FIG. 1 is a flowchart of a method for forming a wet oxidation aperture shape of a VCSEL device according to the present invention; and

FIG. 2 is a schematic top view of the VCSEL wafer of the present invention, showing that the VCSEL wafer has a circular VCSEL mesa with a diameter of 25 um-30 um.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, partial elements not directly related to the present invention are omitted from the illustration, and dimensional proportions among individual elements and the numbers of each element in the accompanying drawings are provided only for ease of understanding but are not intended to limit the actual scale.

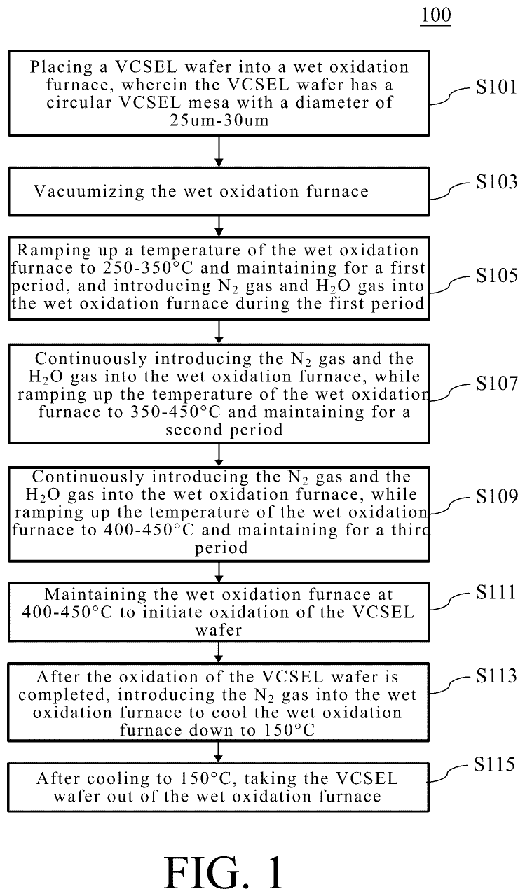

An embodiment of the present invention is shown in FIG. 1, which is a flowchart of a method 100 for forming a wet oxidation aperture shape of a VCSEL device.

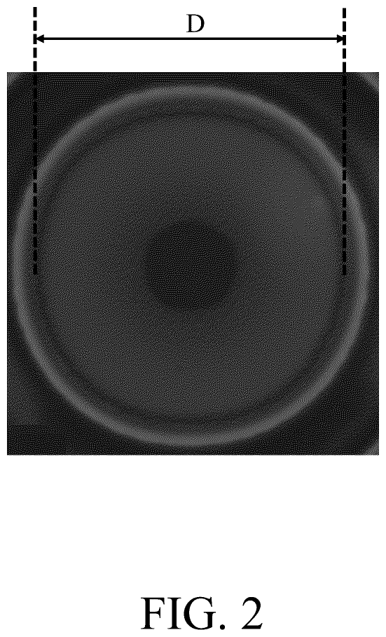

First, in step S101, a VCSEL wafer is placed into a wet oxidation furnace, wherein the VCSEL wafer has a circular VCSEL mesa with a diameter of 25 um-30 um. In this embodiment, the VCSEL wafer may be a 4-inch wafer. For example, FIG. 2 shows a schematic top view of the VCSEL wafer 200 of the present invention, in which the VCSEL wafer 200 has a circular VCSEL mesa with a diameter D of 25 um-30 um. Since a person having ordinary skill in the art can understand that the VCSEL mesa is a structure formed by epitaxial layer growth, masking, exposure and development, and etching during the manufacturing process of 650 nm VCSEL devices, it will not be further discussed herein.

Subsequently, in step S103, the wet oxidation furnace is vacuumized. In step S105, a temperature of the wet oxidation furnace is ramped to 250-350° C. and maintained for a first period, and N₂ gas and H₂O gas are introduced into the wet oxidation furnace during the first period. In step S107, the N₂ gas and the H₂O gas are is continuously introduced into the wet oxidation furnace, while the temperature of the wet oxidation furnace is ramped up to 350-450° C. and maintained for a second period. In step S109, the N₂ gas and the H₂O gas are continuously introduced into the wet oxidation furnace, while the temperature of the wet oxidation furnace is ramped up to 400-450° C. and maintained for a third period. The introduction of the N₂ gas and the H₂O gas in the first period described in step S105 means to start introducing the N₂ gas and the H₂O gas in the constant temperature stage. The continuous introduction of the N₂ gas and the H₂O gas described in steps S107 and S109 means to keep introducing the N₂ gas and the H₂O gas during the ramp and constant temperature stages.

Next, in step S111, the wet oxidation furnace is maintained at 400-450° C. to initiate oxidation of the VCSEL wafer. Specifically, once the temperature of the wet oxidation furnace reaches 400-450° C., it means that the temperature required for oxidation has been reached. At this point, the oxidation is initiated. Then, in step S113, after the oxidation of the VCSEL wafer is completed, the N₂ gas is introduced into the wet oxidation furnace to cool the wet oxidation furnace down to 150° C. Specifically, after the oxidation of the VCSEL wafer begins, once the wet oxidation aperture reaches the predetermined target, it means that the oxidation is completed. As a result, the N₂ gas is then introduced for cooling. In practice, step S113 takes about 1 hour to cool down to 150° C. In step S115, after cooling to 150° C., the VCSEL wafer is taken out of the wet oxidation furnace.

In an embodiment, before step S101, the method 100 may further include the steps: when a wet oxidation process machine is in a standby state, introducing the N₂ gas and the H₂O gas into the wet oxidation furnace to confirm whether a flow rate of the N₂ gas and a flow rate of the H₂O gas are normal; and after confirming that the flow rate of the N₂ gas and the flow rate of the H₂O gas are normal, placing the VCSEL wafer into the wet oxidation furnace. As a result, it can ensure that the wet oxidation process can achieve the expected results. The above wet oxidation process machine refers to a machine that includes a wet oxidation furnace for performing the wet oxidation process.

In an embodiment, the N₂ gas is preferably introduced into the wet oxidation furnace at 10 liters/minute (L/min).

In an embodiment, the H₂O gas is preferably introduced into the wet oxidation furnace at 2 grams/hour (g/h).

In an embodiment, the temperature of the wet oxidation furnace is preferably ramped up to 250-350° C. at a rate of 10˜40° C./min.

In an embodiment, the first period is preferably 6-8 minutes.

In an embodiment, the temperature of the wet oxidation furnace ramped up to 350-450° C. is preferably ramped up at a rate of 10˜30° C./min.

In an embodiment, the second period is preferably 1-2 minutes.

In an embodiment, the temperature of the wet oxidation furnace ramped up to 400-450° C. is preferably ramped up at a rate of 10˜25° C./min.

In an embodiment, the third period is preferably 1˜2 minutes.

It should be noted that the parameters such as the periods and ramp rates mentioned above are provided as examples of optimal parameters to achieve the goal of forming the wet oxidation aperture shape of the epitaxial layer in the 650 nm VCSEL device into a substantially circular shape. However, any adjustments made to these parameters by those skilled in the art based on the steps of the method of the present invention shall fall within the scope of the present invention.

In an embodiment, after step S115, the method 100 may further include the step: taking the VCSEL wafer out of the wet oxidation furnace and allowing the VCSEL wafer to cool naturally at room temperature. In other embodiments, after taking the VCSEL wafer out of the wet oxidation furnace, the VCSEL wafer may be cooled in a non-room temperature environment to accelerate the cooling rate.

In summary, the present invention provides a method for improving the wet oxidation aperture shape of a VCSEL device, which forms the wet oxidation aperture shape of the epitaxial layer of the 650 nm VCSEL device to be substantially circular by adjusting and improving the operation parameters of the wet oxidation furnace. Therefore, the present invention can effectively improve the stability of the 650 nm VCSEL device and increase its reliability and tolerance.

The above embodiments are used only to illustrate the implementations of the present invention and to explain the technical features of the present invention, and are not intended to limit the scope of the present invention. Any modifications or equivalent arrangements that can be easily accomplished by those skilled in this art are considered to fall within the scope of the present invention, and the scope of the present invention should be limited by the claims of the patent application.

What is claimed is:

1. A method for forming a wet oxidation aperture shape of a vertical cavity surface emitting laser (VCSEL) device, comprising the following steps:
placing a VCSEL wafer into a wet oxidation furnace, the VCSEL wafer having a circular VCSEL mesa with a diameter of 25 um-30 um;
vacuumizing the wet oxidation furnace;
ramping up a temperature of the wet oxidation furnace to 250-350° C. and maintaining for a first period, and introducing N₂ gas and H₂O gas into the wet oxidation furnace during the first period;
continuously introducing the N₂ gas and the H₂O gas into the wet oxidation furnace, while ramping up the temperature of the wet oxidation furnace to 350-450° C. and maintaining for a second period;
continuously introducing the N₂ gas and the H₂O gas into the wet oxidation furnace, while ramping up the temperature of the wet oxidation furnace to 400-450° C. and maintaining for a third period;
maintaining the wet oxidation furnace at 400-450° C. to initiate oxidation of the VCSEL wafer;
after the oxidation of the VCSEL wafer is completed, introducing the N₂ gas into the wet oxidation furnace to cool the wet oxidation furnace down to 150° C.; and
after cooling to 150° C., taking the VCSEL wafer out of the wet oxidation furnace.

2. The method of claim 1, wherein before placing the VCSEL wafer into the wet oxidation furnace, the method further comprises the following steps:
when a wet oxidation process machine is in a standby state, introducing the N₂ gas and the H₂O gas into the wet oxidation furnace to confirm whether a flow rate of the N₂ gas and a flow rate of the H₂O gas are normal; and
after confirming that the flow rate of the N₂ gas and the flow rate of the H₂O gas are normal, placing the VCSEL wafer into the wet oxidation furnace.

3. The method of claim 1, wherein the N₂ gas is introduced into the wet oxidation furnace at 10 liters/minute (L/min).

4. The method of claim 1, wherein the H₂O gas is introduced into the wet oxidation furnace at 2 grams/hour (g/h).

5. The method of claim 1, wherein the temperature of the wet oxidation furnace is ramped up to 250-350° C. at a rate of 10˜40° C./min.

6. The method of claim 1, wherein the first period is 6-8 minutes.

7. The method of claim 1, wherein the temperature of the wet oxidation furnace ramped up to 350-450° C. is ramped up at a rate of 10˜30° C./min.

8. The method of claim 1, wherein the second period is 1-2 minutes.

9. The method of claim 1, wherein the temperature of the wet oxidation furnace ramped up to 400-450° C. is ramped up at a rate of 10˜25° C./min.

10. The method of claim 1, wherein the third period is 1˜2 minutes.

11. The method of claim 1, further comprising the following step:
taking the VCSEL wafer out of the wet oxidation furnace and allowing the VCSEL wafer to cool naturally at room temperature.
